(19) United States
(12) Patent Application Publication
(10) Pub. No.: US 2026/0092400 A1
(43) Pub. Date: Apr. 2, 2026

(54) SiC CRYSTAL AND METHOD FOR MANUFACTURING SiC CRYSTAL

(71) Applicant: Resonac Corporation, Tokyo (JP)

(72) Inventor: Shota OTOGAWA, Tokyo (JP)

(73) Assignee: Resonac Corporation, Tokyo (JP)

(21) Appl. No.: 19/344,905

(22) Filed: Sep. 30, 2025

(30) Foreign Application Priority Data
Sep. 30, 2024 (JP) 2024-171181

(51) Int. Cl. C30B 29/36; C30B 33/00

(52) U.S. Cl. CPC C30B 29/36; C30B 33/00

(57) ABSTRACT

A SiC crystal according to the present embodiment has a first surface which is one surface in a stacking direction, wherein in a case where a waviness curve of the first surface is measured along a first measurement line that passes through a center of the first surface and extends in a <1-100> direction, a lowest point of the waviness curve on the first measurement line is dislocated from the center.

### BACKGROUND OF THE INVENTION

### Field of the Invention

The present invention relates to a SiC crystal, a SiC boule, and a method for manufacturing a SiC crystal.

Priority is claimed on Japanese Patent Application No. 2024-171181, filed September 30, 2024, the content of which is incorporated herein by reference.

### Description of Related Art

Silicon carbide (SiC) has a dielectric breakdown field one order of magnitude larger and a band gap three times larger than silicon (Si). In addition, silicon carbide (SiC) has properties such as a thermal conductivity about three times higher than silicon (Si). For this reason, silicon carbide (SiC) is expected to be applied to power devices, high frequency devices, high temperature operating devices, and the like. In recent years, SiC epitaxial wafers have come to be used for the above-described semiconductor devices.

A SiC epitaxial wafer is obtained by stacking a SiC epitaxial layer on the surface of a SiC substrate. The SiC substrate is cut out from a SiC ingot. The SiC ingot is a SiC crystal processed in a cylindrical shape.

The SiC ingot may be shipped with its surface ground. For example, Patent Document 1 discloses a grinding device for semiconductor wafers.

### Patent Documents

[Patent Document 1] Japanese Unexamined Patent Application, First Publication No. 2023-307

### SUMMARY OF THE INVENTION

When a SiC substrate is cut out from a SiC ingot, a multi-wire saw is used. A multi-wire saw has blades spaced at regular intervals, and thus a plurality of SiC substrates can be cut out from a SiC ingot in one processing. In addition, in order to improve the processing efficiency of processing using a multi-wire saw, a plurality of SiC ingots may be connected to each other with an adhesive or the like. However, when a plurality of SiC ingots are connected to each other, a cutting defect may occur.

The present disclosure has been made in consideration of the above-mentioned problems, and an object of the present disclosure is to provide a SiC crystal in which a defect is less likely to occur when a joined body obtained by joining crystals is cut with a multi-wire saw and a method for manufacturing the same.

After extensive research, the present inventors have found that the cause of the above-described problems is a joining defect that occurs when a plurality of SiC crystals are joined to each other. In addition, the present inventors also have found that the surface condition of a first surface of a SiC crystal, which is a joining surface, has a significant effect on the adhesiveness when a plurality of SiC crystals are joined to each other. In order to solve the above problems, the present disclosure provides the following means.

(1) A SiC crystal according to a first aspect has a first surface which is one surface in a stacking direction, wherein in a case where a waviness curve of the first surface is measured along a first measurement line that passes through a center of the first surface and extends in a <1-100> direction, a lowest point of the waviness curve on the first measurement line is dislocated from the center.

(2) In the SiC crystal according to the above aspect, in a case where a waviness curve of the first surface is measured along a second measurement line that passes through a center of the first surface and extends in an <11-20> direction, a lowest point of the waviness curve on the second measurement line may be dislocated from the center.

(3) In the SiC crystal according to the above aspect, a surface roughness Ra of the first surface which is measured along the first measurement line may be 20 nm or less.

(4) In the SiC crystal according to the above aspect, a surface roughness Ra of the first surface which is measured along a second measurement line that passes through a center of the first surface and extends in an <11-20> direction may be 30 nm or less.

(5) In the SiC crystal according to the above aspect, the first surface may have abrasive grain trajectories. An intersection point at which the abrasive grain trajectories overlap with each other most may be dislocated from the center.

(6) In the SiC crystal according to the above aspect, a difference between a highest point and a lowest point of the waviness curve on the first measurement line may be 3.5 μm or less.

(7) In the SiC crystal according to the above aspect, a difference between a highest point and a lowest point of the waviness curve on the second measurement line may be 3.5 μm or less.

(8) A SiC crystal according to a second aspect has a first surface which is one surface in a stacking direction, wherein in a case where a waviness curve of the first surface is measured along a first measurement line that passes through a center of the first surface and extends in a <1-100> direction, a difference between a highest point and a lowest point of the waviness curve on the first measurement line is 3.5 μm or less.

(9) In the SiC crystal according to the above aspect, in a case where a waviness curve of the first surface is measured along a second measurement line that passes through a center of the first surface and extends in an <11-20> direction, a difference between a highest point and a lowest point of the waviness curve on the second measurement line may be 3.5 μm or less.

(10) In the SiC crystal according to the above aspect, a surface roughness Ra of the first surface which is measured along the first measurement line may be 20 nm or less.

(11) In the SiC crystal according to the above aspect, a surface roughness Ra of the first surface which is measured along a second measurement line that passes through a center of the first surface and extends in an <11-20> direction may be 30 nm or less.

(12) In the SiC crystal according to the above aspect, the first surface may have abrasive grain trajectories. An intersection point at which the abrasive grain trajectories overlap with each other most may be dislocated from the center.

(13) In the SiC crystal according to the above aspect, the lowest point of the waviness curve on the first measurement line may be dislocated from the center.

(14) In the SiC crystal according to the above aspect, the lowest point of the waviness curve on the second measurement line may be dislocated from the center.

(15) In the SiC crystal according to the above aspect, the SiC crystal has a diameter of 145 mm or greater.

(16) A method for manufacturing a SiC crystal according to a fourth aspect, includes: a step of placing a workpiece made of a SiC crystal on a support table; and a step of grinding a first surface of the workpiece by bringing the workpiece placed on the support table rotating in a first direction into contact with a grinding disk rotating in a second direction opposite to the first direction. The grinding disk is disposed at a position facing the support table such that a center of the grinding disk does not coincide with a center of the support table. A center of the workpiece is dislocated from the center of the support table.

(17) In the method for manufacturing a SiC crystal according to the above aspect, a distance between the center of the workpiece and the center of the support table may be greater than or equal to a radius of the workpiece.

(18) In the method for manufacturing a SiC crystal according to the above aspect, a distance between the center of the workpiece and the center of the support table may be equal to a radius of the workpiece.

(19) In the method for manufacturing a SiC crystal according to the above aspect, the workpiece may have a diameter of 149 mm or greater.

(20) In the method for manufacturing a SiC crystal according to the above aspect, in a case where a distance between the center of the workpiece and the center of the support table is defined as x and a rotation speed of the support table is defined as n, a peripheral speed of the support table at a placement position of the workpiece may be 2πxn, and in a case where a speed at which the grinding disk approaches the workpiece is defined as f, 2πxn/f, which is a ratio of a cutting speed to the peripheral speed, may satisfy 2πxn/f ≤ 1.03×10⁶.

In the SiC crystal or the SiC boule according to the above aspect, a defect is less likely to occur when a joined body obtained by joining crystals is cut with a multi-wire saw. In addition, the method for manufacturing a SiC crystal can produce a SiC crystal in which a defect is less likely to occur when a joined body obtained by joining crystals is cut with a multi-wire saw.

### BRIEF DESCRIPTION OF THE DRAWINGS

FIG. 1 is a perspective view of a SiC crystal according to a first embodiment.

FIG. 2 is a plan view of a first surface of the SiC crystal according to the first embodiment.

FIG. 3 shows a waviness curve of the first surface of the SiC crystal according to the first embodiment, which is measured along a first measurement line.

FIG. 4 shows a waviness curve of the first surface of the SiC crystal according to the first embodiment, which is measured along a second measurement line.

FIG. 5 is a plan view of the first surface of the SiC crystal according to the first embodiment.

FIG. 6 is a schematic view of a grinding device used in producing the SiC crystal according to the first embodiment.

FIG. 7 is a plan view of the grinding device used in producing the SiC crystal according to the first embodiment.

FIG. 8 shows a measurement result of a waviness curve of a first surface of a SiC crystal of Example 1.

FIG. 9 shows a measurement result of a waviness curve of a first surface of a SiC crystal of Example 2.

FIG. 10 shows a measurement result of a waviness curve of a first surface of a SiC crystal of Example 3.

FIG. 11 shows a measurement result of a waviness curve of a first surface of a SiC crystal of Comparative Example 1.

FIG. 12 shows a measurement result of a waviness curve of a first surface of a SiC crystal of Example 7.

### DETAILED DESCRIPTION OF THE INVENTION

Hereinafter, the present embodiment will be described in detail with reference to the drawings as appropriate. In the drawings which will be used in the following description, a feature portion may be enlarged for convenience to make a feature of the present embodiment easy to understand, and the dimensional ratios of each constituent element and the like may be different from the actual ones. The materials, dimensions, and the like which will be exemplified in the following description are examples, and the present disclosure is not limited thereto and can be appropriately modified and carried out within the scope in which the gist of the present invention is not changed.

In the present specification, an individual orientation is indicated by [ ], a collective orientation is indicated by < >, an individual plane is indicated by ( ), and a collective plane is indicated by { }. For negative indices, a “−” (bar) is customarily placed above the number in crystallography, but in the present specification, a negative sign is placed before the number.

First, directions will be defined. A stacking direction (a crystal growth direction) of a SiC single crystal is defined as a Z direction. The Z direction may be a <0001> direction or may be tilted by an offset angle relative to the <0001> direction. One direction on a plane orthogonal to the Z direction is defined as an X direction. The X direction is, for example, a <1−100> direction. A Y direction is, for example, an <11−20> direction.

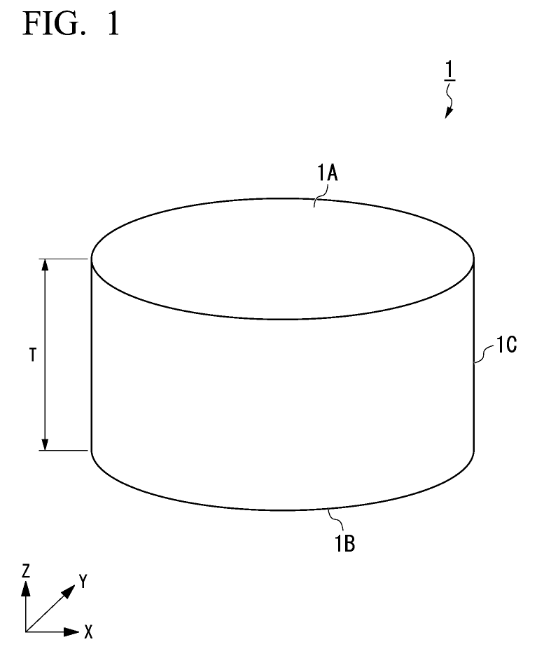

FIG. 1 is a perspective view of a SiC crystal 1 according to the present embodiment. The SiC crystal 1 may be a SiC boule, a seed crystal used in producing the SiC boule, or a SiC substrate. The SiC boule is also called a SiC ingot. The SiC crystal 1 is made of, for example, n-type SiC. The polytype of the SiC crystal 1 is not particularly limited and may be any of 2H, 3C, 4H, and 6H. The SiC crystal 1 is, for example, 4H-SiC.

The SiC crystal 1 is a cylindrical columnar body. The SiC crystal 1 has a first surface 1A, a second surface 1B, and a side surface 1C. Each of the first surface 1A and the second surface 1B is a surface of one of end portions of the SiC crystal 1 in the Z direction. The first surface 1A and the second surface 1B are opposite to each other. The first surface 1A may be a Si-plane or a C-plane. The side surface 1C connects the first surface 1A and the second surface 1B to each other.

The first surface 1A and the second surface 1B may have or may not have a portion that has an offset angle with respect to a (0004) plane in the <11-20> direction. The offset angle is an angle between a plane perpendicular to the Z direction, which is a thickness direction of the SiC crystal 1, and the (0004) plane. The offset angle is more than 0° and 10° or less, preferably 0.1° or more and 8° or less, more preferably 3.5° or more and 4.5° or less, and even more preferably 4°, for example. In a case in which there is no offset angle, the SiC crystal 1 has undergone just-plane growth.

A thickness T of the SiC crystal 1 in the Z direction is preferably 30 mm or more, more preferably 40 mm or more, and particularly preferably 50 mm or more, for example. When the thickness T of the SiC crystal 1 is sufficiently great, the influence of warpage and the like of the SiC crystal 1 can be ignored when measuring a waviness curve, which will be described below. The thickness T of the SiC crystal 1 in the Z direction is preferably 300 mm or less, for example. In addition, the thickness T of the SiC crystal 1 may be less than 30 mm, may be 20 mm or less, or may be 10 mm or less. In a case in which the thickness T of the SiC crystal 1 is small, the SiC crystal 1 is adsorbed on a flat surface and the waviness curve is measured. When the SiC crystal 1 is adsorbed on the flat surface, the influence of warpage and the like of the SiC crystal 1 can be ignored.

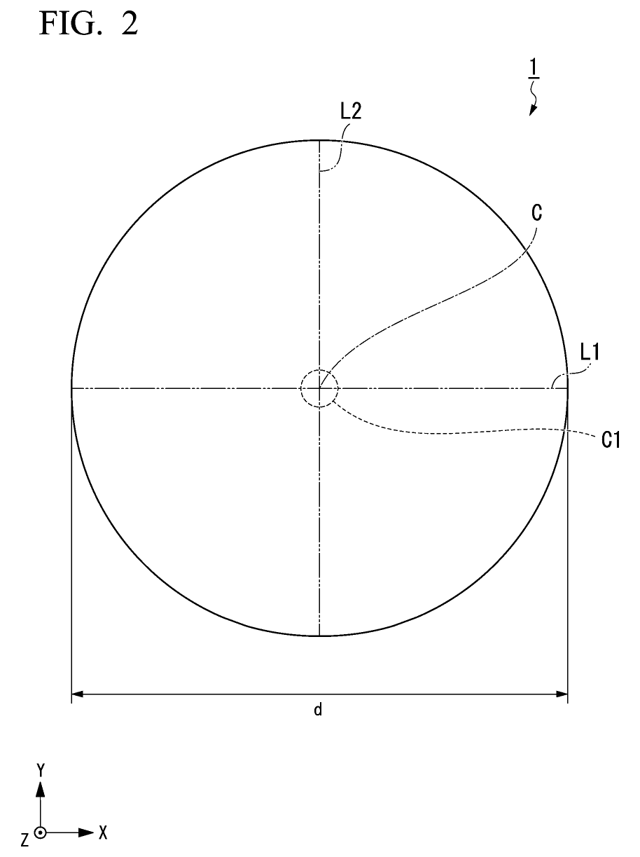

FIG. 2 is a plan view of the first surface 1A of the SiC crystal 1 according to the present embodiment in the Z direction. A planar view shape of the SiC crystal 1 is substantially circular.

A diameter d of the SiC crystal 1 is 145 mm or more, and preferably 149 mm or more, for example. In addition, the diameter d of the SiC crystal 1 is preferably 155 mm or less and more preferably 151 mm or less. In addition, the diameter d of the SiC crystal 1 may be 195 mm or more, and may be preferably 199 mm or more, for example. In addition, the diameter d of the SiC crystal 1 may be preferably 205 mm or less, and may be more preferably 201 mm or less. The diameter d of the SiC crystal 1 may be 295 mm or more, and may be preferably 299 mm or more. The diameter d of the SiC crystal 1 may be 305 mm or less, and may be preferably 301 mm or less. Here, the diameter d of the SiC crystal 1 is the minimum diameter of the SiC crystal 1. For example, in a case in which the SiC crystal 1 is a SiC boule, the minimum value of the diameter of a SiC substrate that can be acquired corresponds to the minimum diameter of the SiC crystal 1. For example, in a case in which the diameter of the SiC crystal 1 varies depending on the position in the Z direction, a diameter at a height position at which the diameter becomes minimum corresponds to the diameter d.

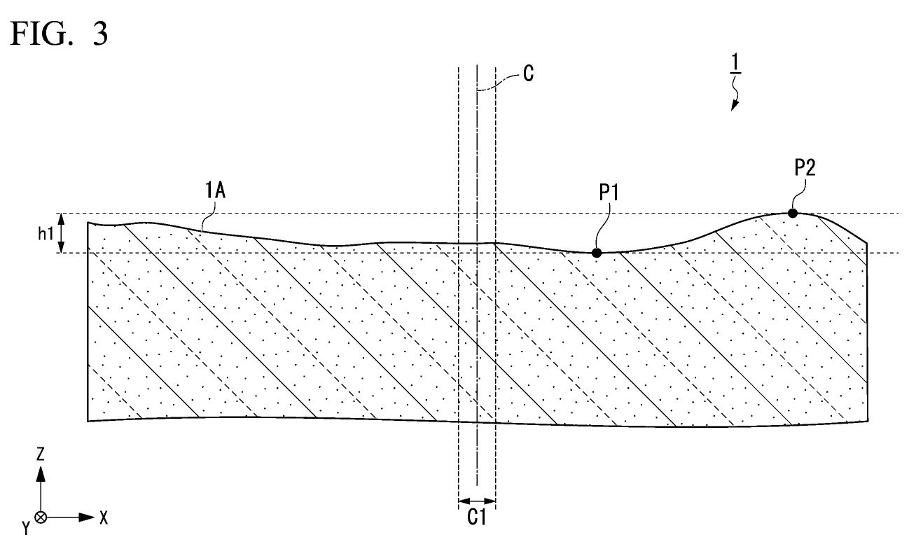

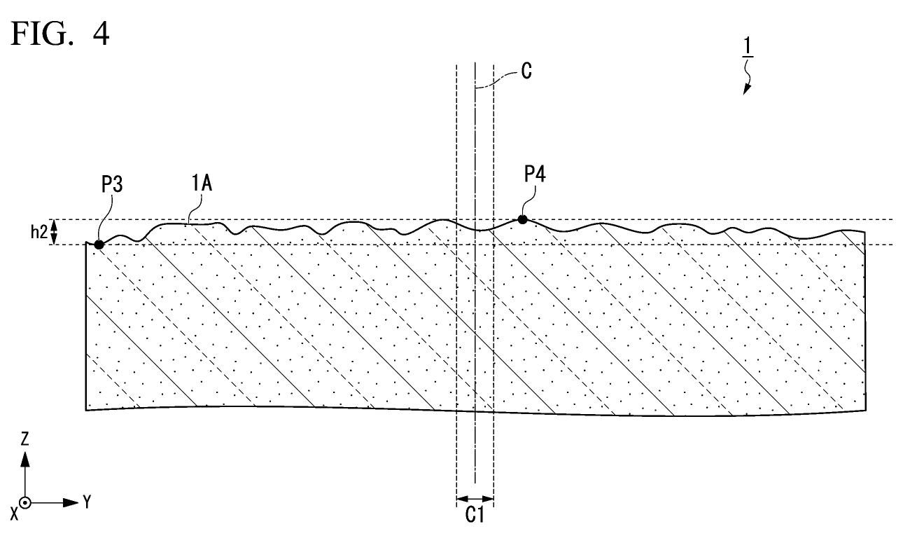

The first surface 1A of the SiC crystal 1 is ground. The first surface 1A has a slightly wavy surface due to grinding. FIG. 3 shows a waviness curve of the first surface 1A of the SiC crystal 1, which is measured along a first measurement line L1. FIG. 4 shows a waviness curve of the first surface 1A of the SiC crystal 1, which is measured along a second measurement line L2. The first measurement line L1 is a line that passes through a center C of the first surface 1A in a plan view in the Z direction and extends in the <1-100> direction. The second measurement line L2 is a line that passes through a center C when the first surface 1A is viewed in a plan view in the Z direction and extends in the <11-20> direction. A center of a circumscribing circle of the SiC crystal 1 in a plan view is defined as the center C.

In a case in which the thickness of the SiC crystal 1 is 30 mm or more, the waviness curve of the first surface 1A is measured in a state in which the SiC crystal 1 is placed on the flat surface. In a case in which the thickness of the SiC crystal 1 is less than 30 mm, the waviness curve of the first surface 1A is measured in a state in which the SiC crystal 1 is adsorbed on the flat surface. When the thickness of the SiC crystal 1 is sufficiently great, or the SiC crystal 1 is adsorbed to the flat surface, the influence of warpage and the like of first surface 1A caused by factors other than waviness caused by grinding can be ignored.

The waviness curve is measured using, for example, SURFCOM NEX 001 DX22 manufactured by Tokyo Seimitsu Co., Ltd. An outer peripheral region including the outside of an acquisition region of the device is not included in the measurement range of the waviness curve. The outer peripheral region is a range of 4 mm from an outer peripheral edge. For example, in a case in which the diameter of the SiC crystal 1 is 6 inches (approximately 150 mm), the range of 4 mm from the outer peripheral edge is outside a measurement region, and a measurement length is 142 mm. A measurement speed was 3.0 mm/sec, a measurement range was ±500 mm, a calculation standard was JIS-’01/13 standard, shape removal corresponding to inclination correction was performed using a least-squares straight line, a cut-off type was Gaussian, a cut-off wavelength was 2.5 mm, and a measurement type was a filtered waviness curve. The filtered waviness curve is a curve obtained by removing roughness components with short waviness wavelengths from a profile curve obtained by tracing a surface of a measurement surface with a probe. The cut-off wavelength indicates the range of the roughness components to be removed.

As shown in FIG. 3, the profile of the first surface 1A of the SiC crystal 1, which is measured along the first measurement line L1, is wavy. As shown in FIG. 3, for example, a lowest point P1 of the waviness curve is dislocated from the center C. The lowest point P1 of the waviness curve is preferably dislocated from a central portion C1 within 4% of the diameter from the center C. For example, the central portion C1 is a region within a radius of 3 mm from the center C. The lowest point P1 is preferably located outside the range within 5% of the diameter from the center C, and more preferably outside the range within 10% of the diameter from the center C.

As shown in FIG. 4, the profile of the first surface 1A of the SiC crystal 1, which is measured along the second measurement line L2, is wavy. As shown in FIG. 4, for example, a lowest point P3 of the waviness curve is dislocated from the center C. The lowest point P3 of the waviness curve is preferably dislocated from a central portion C1 within 4% of the diameter from the center C. The lowest point P3 is preferably located outside the range within 5% of the diameter from the center C, and more preferably outside the range within 10% of the diameter from the center C.

When the position of the lowest point P1 or the lower position P3 of the waviness curve is dislocated from the center C, defects are less likely to occur even when a joined body obtained by joining the SiC crystals 1 to each other is cut with a multi-wire saw. The multi-wire saw has a blade extending in the Y direction and cuts the SiC crystal 1 by moving the joined body in the X direction relative to the blade. When cutting the SiC crystal 1 with the multi-wire saw, stress that causes a cut portion of the SiC crystal 1 to shift in the X direction or the Y direction, stress that causes a cut portion of the SiC crystal 1 to rotate in an XY plane on the basis of the center C, and stress that causes a cut portion of the SiC crystal 1 to incline in the Z direction are applied to the SiC crystal 1. The center C and the central portion C1 of the first surface 1A are subjected to these stresses strongly.

In a case in which the SiC crystals 1 are joined to each other, portions between the lowest point P1 and the lowest point P3 of the waviness curve and an adjacent SiC crystal 1 are filled with an adhesive. In a case in which the lowest point P1 or the lowest point P3 coincides with the center C, the center C, to which the strong stress is applied, is joined by the adhesive and thus is likely to be subjected to the influence of the stress. As a result, the joined body of the SiC crystals 1 may become misaligned at a joining interface. In a case in which the positions of the lowest point P1 or the lowest point P3 and the center C are dislocated from each other, the position that is likely to be subjected to the stress and the position to which the stress is likely to be applied are dislocated from each other, and thus a joining defect in the SiC crystal 1 can be suppressed more effectively than in a case in which the lowest point P1 or the lowest point P3 coincides with the center C.

A difference h1 in height in the Z direction between the lowest point P1 and a highest point P2 of the waviness curve (see FIG. 3) is, for example, 3.5 μm or less. The difference h1 in height in the Z direction between the lowest point P1 and the highest point P2 of the waviness curve is preferably 2.5 μm or less, more preferably 2.0 μm or less, still more preferably 1.7 μm or less, even more preferably 1.2 μm or less, and particularly preferably 1.0 μm or less.

Similarly, a difference h2 in height in the Z direction between the lowest point P3 and a highest point P4 of the waviness curve (see FIG. 4) is, for example, 3.5 μm or less. The difference h2 in height in the Z direction between the lowest point P3 and the highest point P4 of the waviness curve is preferably 2.5 μm or less, more preferably 2.0 μm or less, still more preferably 1.7 μm or less, even more preferably 1.2 μm or less, and particularly preferably 1.0 μm or less.

When the difference between the lowest point and the highest point of the waviness curve is large, a depth of the portion filled with the adhesive becomes great. When the depth of the portion filled with the adhesive is great, the SiC crystal 1 is likely to be subjected to the influence of the stress when the SiC crystal 1 is cut. When the difference between the lowest point and the highest point of the waviness curve is large, the possibility of variation in thickness of the SiC substrate after cutting is increased. In contrast to this, when the difference between the lowest point and the highest point of the waviness curve is sufficiently small, it is possible to decrease the probability that a cutting defect of the joined body of the SiC crystal 1 occurs.

A surface roughness Ra of the first surface 1A measured along the first measurement line L1 is, for example, preferably 20 nm or less, more preferably 17 nm or less, even more preferably 16 nm or less, and particularly preferably 13 nm or less.

In addition, a surface roughness Ra of the first surface 1A measured along the second measurement line L2 is, for example, preferably 30 nm or less, more preferably 29 nm or less, even more preferably 14 nm or less, and particularly preferably 13 nm or less.

The smaller the surface roughness Ra of the first surface 1A, the greater a joining area between the SiC crystals 1, and thus a cutting defect of the joined body of the SiC crystals 1 is less likely to occur.

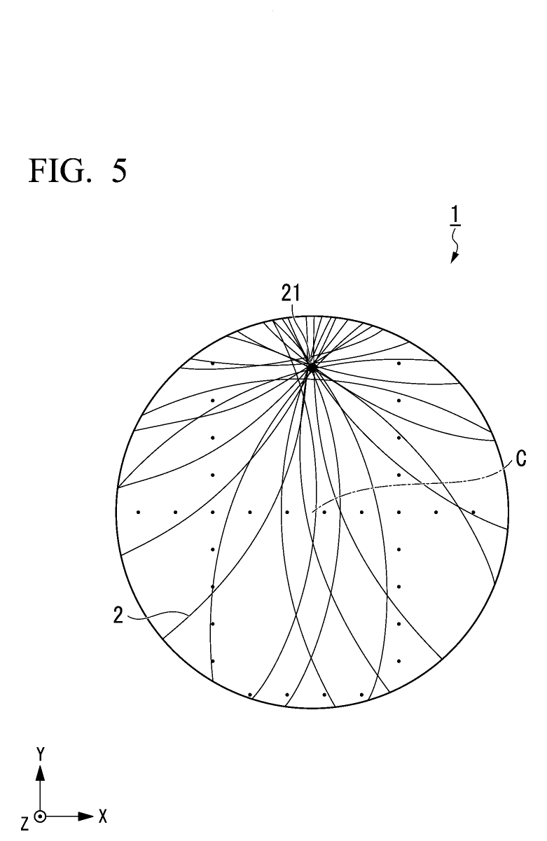

In addition, an abrasive grain trajectory 2 may be observed on the first surface 1A of the SiC crystal 1, as shown in FIG. 5. The abrasive grain trajectory 2 is a grinding mark left after grinding the SiC crystal 1. The abrasive grain trajectory 2 may be a grinding trajectory because it corresponds to the grinding mark. The abrasive grains may be contained in a grinding wheel used for grinding. During the grinding, the abrasive grain trajectory 2 is formed by a rotating SiC crystal 1 and a rotating grinding disk. The abrasive grain trajectory 2 traces a pattern. The abrasive grain trajectory 2 is, for example, a part of a rose curve. The abrasive grain trajectory 2 is faintly visible as a white line on the first surface 1A having a mirror surface shape. There are a plurality of abrasive grain trajectories 2 on the first surface 1A, and an intersection point 21 at which the abrasive grain trajectories 2 intersect with each other can be seen. The intersection point 21 at which the abrasive grain trajectories 2 overlap with each other most is, for example, dislocated from the center C of the first surface 1A. A portion at which the abrasive grain trajectory 2 is formed may be deeper than a portion at which the abrasive grain trajectory 2 is not formed, and when the intersection point 21 is dislocated from the center C, a joining defect between the SiC crystals 1 can be suppressed. In addition, the intersection point 21 at which the abrasive grain trajectories 2 overlap with each other most is preferably, for example, dislocated from the central portion C1 of the first surface 1A.

In addition, a relationship at the first surface 1A of the SiC crystal 1 may also be satisfied at the second surface 1B. When the second surface 1B satisfies the same relationship as the first surface 1A, a cutting defect is less likely to occur when a plurality of SiC crystals 1 are joined to each other and cut.

For example, a lowest point of a waviness curve measured along a third measurement line on the second surface 1B is preferably dislocated from the center of the second surface 1B and is preferably dislocated from the central portion within 4% of the diameter from the center of the second surface 1B. The third measurement line is a line that passes through the center when the second surface 1B is viewed in a plan view in the Z direction and extends in the <1-100> direction. The center and the central portion of the second surface 1B are defined in the same manner as the center and the central portion of the first surface 1A.

In addition, for example, a lowest point of a waviness curve measured along a fourth measurement line on the second surface 1B is preferably dislocated from the center of the second surface 1B and is preferably dislocated from the central portion within 4% of the diameter from the center of the second surface 1B. The fourth measurement line is a line that passes through the center when the second surface 1B is viewed in a plan view in the Z direction and extends in the <11-20> direction.

In addition, a difference in height in the Z direction between the lowest point and the highest point of the waviness curve measured on the second surface 1B along the third measurement line is preferably 3.5 μm or less, more preferably 2.5 μm or less, still more preferably 2.0 μm or less, still more preferably 1.7 μm or less, even more preferably 1.2 μm or less, and particularly preferably 1.0 μm or less.

In addition, a difference in height in the Z direction between the lowest point and the highest point of the waviness curve measured on the second surface 1B along the fourth measurement line is preferably 3.5 μm or less, more preferably 2.5 μm or less, still more preferably 2.0 μm or less, still more preferably 1.7 μm or less, even more preferably 1.2 μm or less, and particularly preferably 1.0 μm or less.

In addition, a surface roughness Ra of the second surface 1B measured along the third measurement line is, for example, preferably 20 nm or less, more preferably 17 nm or less, even more preferably 16 nm or less, and particularly preferably 13 nm or less.

In addition, a surface roughness Ra of the second surface 1B measured along the fourth measurement line is, for example, preferably 30 nm or less, more preferably 29 nm or less, even more preferably 14 nm or less, and particularly preferably 13 nm or less.

In addition, on the second surface 1B, an intersection point at which abrasive grain trajectories overlap with each other most is preferably, for example, dislocated from the center of the second surface 1B.

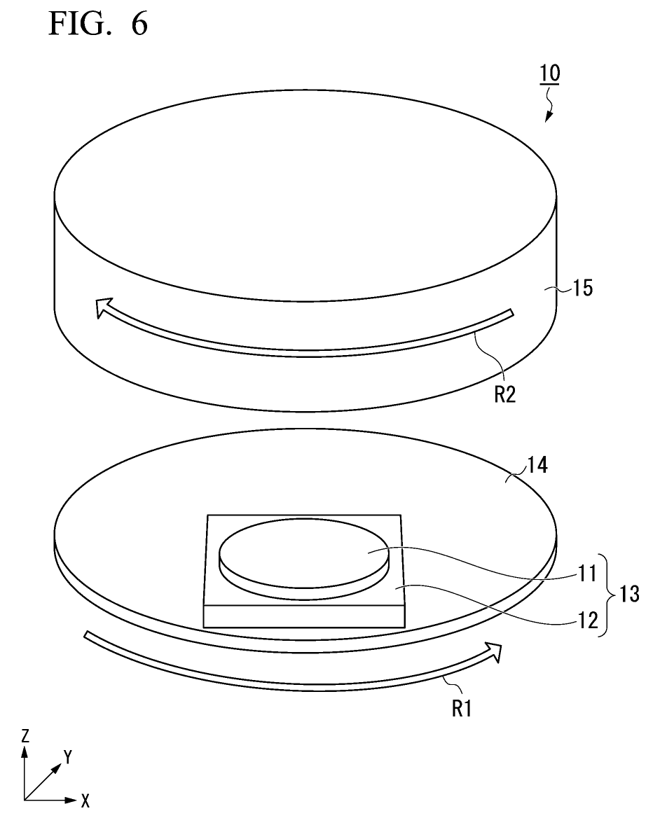

Next, a method for manufacturing the SiC crystal 1 according to the first embodiment will be described. The method for manufacturing the SiC crystal 1 includes a preparation step and a grinding step. FIG. 6 is a schematic view of a grinding device 10 used in producing the SiC crystal 1 according to the first embodiment.

In the preparation step, a work 13 on which a workpiece 11 made of the SiC crystal is placed is placed on a support table 14. Here, an example in which the workpiece 13 is placed on the support table 14 is shown, but the workpiece 11 may also be placed directly on the support table 14.

The workpiece 11 is the SiC crystal 1 in a state before grinding and has the same configuration as the SiC crystal 1 except for a surface state of the first surface 1A. For example, the diameter of the workpiece 11 is the same as the diameter d of the SiC crystal 1 and is, for example, 149 mm or more.

The work 13 includes a workpiece 11 and a plate 12. The plate 12 is used to improve the flatness of a processed surface of the workpiece 11. The plate 12 is made of, for example, stainless steel (SUS). In a case in which the workpiece 11 is placed directly on the support table 14, the plate 12 is not necessary.

A grinding disk 15 is disposed at a position opposite to the support table 14. The grinding disk 15 has, for example, a plurality of grinding wheels disposed in a ring shape along an outer periphery of the grinding disk 15.

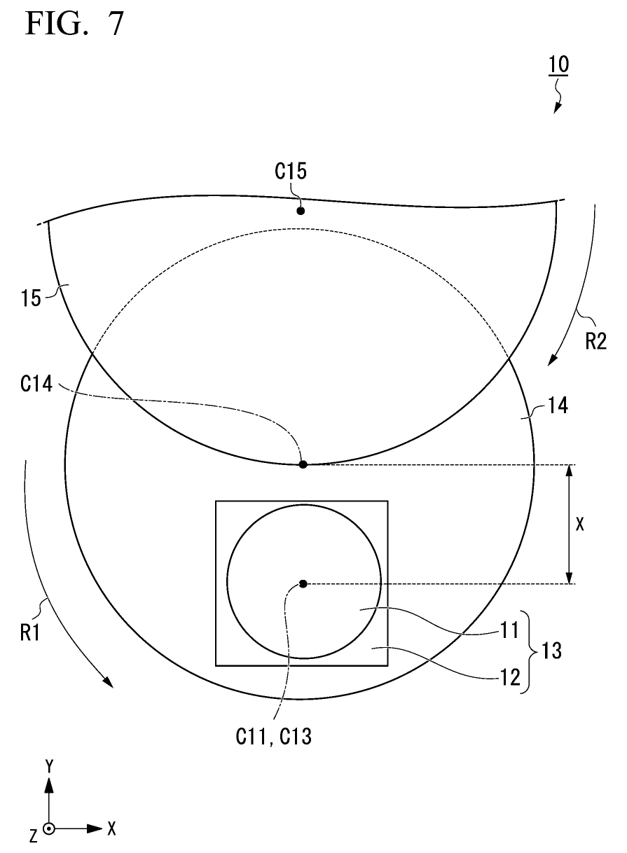

FIG. 7 is a plan view of the grinding device 10 used in producing the SiC crystal 1 according to the first embodiment.

A center C15 of the grinding disk 15 is dislocated from a center C14 of the support table 14. As shown in FIG. 7, the outer periphery of the grinding disk 15 may be disposed so as to pass through the center C14 of the support table 14. When the outer periphery of the grinding disk 15 is disposed so as to pass through the center C14 of the support table 14, the difference h1 in height in the Z direction between the lowest point P1 and the highest point P2 of the waviness curve and the difference h2 in height in the Z direction between the lowest point P3 and the highest point P4 of the waviness curve are 2.0 μm or less. The diameter of the grinding disk 15 is preferably greater than the greatest length between the center C14 and the outer periphery of the workpiece 11, for example. A radial length of each of the grinding wheels disposed in a ring shape on the grinding disk 15 is preferably greater than the diameter of the workpiece 11, for example.

The workpiece 11 is placed on the support table 14 such that a center C11 of the workpiece 11 and the center C14 of the support table 14 do not coincide with each other. The center C11 of the workpiece 11 is dislocated from the center C14 of the support table 14. The center C11 of the workpiece 11 basically coincides with a center C13 of the work 13. The center C11 of the workpiece 11 may be dislocated from the center C13 of the work 13. A distance x between the center C14 and the center C11 is preferably greater than or equal to a radius of the workpiece 11, for example, and more preferably equal to the radius of the workpiece 11.

For example, in a case in which the diameter of the workpiece 11 is 150 mm (6 inches), the distance x between the center C14 and the center C11 is preferably 50 mm or more and 200 mm or less, more preferably 50 mm or more and 150 mm or less, even more preferably 50 mm or more and 100 mm or less, and particularly preferably 75 mm or more and 100 mm or less.

Next, a grinding step is carried out. In the grinding step, the workpiece 11 placed on the support table 14 rotating in a first direction R1 is brought into contact with the grinding disk 15 rotating in a second direction R2, and the first surface of the workpiece 11 is ground. The second direction R2 is a direction opposite to the first direction R1. The grinding disk 15 is movable in the Z direction. By lowering the grinding disk 15 toward the workpiece 11, the workpiece 11 and the grinding disk 15 come into contact with each other.

When the distance between the center C11 of the workpiece 11 and the center C14 of the support table 14 is defined as x and a rotation speed of the support table 14 is defined as n, a peripheral speed of the support table 14 at a placement position of the workpiece 11 is 2πxn. When a speed at which the grinding disk 15 approaches the workpiece 11 is defined as f, a ratio of a cutting speed to the peripheral speed of the work 13 is expressed as 2πxn/f. It is preferable that 2πxn/f satisfy 2πxn/f ≤ 1.03×10⁶. When this condition is satisfied, the load on the grinding disk 15 and the workpiece 11 can be reduced, and damage to the grinding wheel of the grinding disk 15 and the workpiece 11 can be suppressed.

By grinding the workpiece 11 in the grinding step, the SiC crystal 1 according to the present embodiment is obtained. By placing the workpiece 11 on the support table 14 such that the center C11 of the workpiece 11 and the center C14 of the support table 14 do not coincide with each other, it is possible to prevent the abrasive grain trajectories 2 from being densely located at the center C11 of the workpiece 11.

In the SiC crystal 1 according to the present embodiment, the position of the lowest point of the waviness curve and the position of the center C are dislocated from each other, and thus the position that is likely to be subjected to the stress and the position to which the stress is likely to be applied can be dislocated from each other, thereby preventing the joined body of the SiC crystal 1 from peeling off at the joining interface.

In addition, in the SiC crystal 1 according to the present embodiment, the difference between the lowest point and the highest point of the waviness curve is small, and thus the probability that the blade of the multi-wire saw passes through the interface between the SiC crystal 1 and the adhesive is reduced, thereby preventing the blade of the multi-wire saw from twisting during cutting. As a result, it is possible to suppress variation in thickness of the SiC substrate after cutting and to decrease the probability that a cutting defect of the joined body of the SiC crystal 1 occurs.

In the SiC crystal 1 according to the present embodiment, it is not necessary that the position of the lowest point of the waviness curve and the position of the center C are dislocated from each other and the difference between the lowest point and the highest point of the waviness curve is small at the same time. Even if only one of the conditions is satisfied, a cutting defect of the joined body can be suppressed compared to the case in which no countermeasure is taken.

Although the preferable embodiment of the present disclosure has been described in detail above, the present disclosure is not limited to a specific embodiment, and various modifications and changes can be made within the scope of the gist of the present disclosure described in the claims.

### [Examples]

### Example 1

A SiC crystal (SiC ingot) having a diameter of 150 mm (6 inches) and a thickness of 20 mm was prepared. As shown in FIGS. 6 and 7, the SiC crystal, which is a workpiece 11, was placed on a support table 14. The diameter of the support table 14 was 700 mm. A distance x between a center C14 of the support table 14 and a center C11 of the workpiece 11 was 50 mm. The grinding disk 15 used cup-type grinding wheels in which the grinding wheels were disposed in a ring shape. A ring on which the grinding wheels of a grinding disk 15 were disposed had an outer diameter of 400 mm and an inner diameter of 385 mm. During grinding, the grinding disk 15 is positioned such that the outer periphery of the ring on which the grinding wheels of the grinding disk 15 are disposed passes through the center C14 of the support table 14.

Next, the support table 14 and the grinding disk 15 were rotated in opposite directions, and the workpiece 11 placed on the support table 14 was brought into contact with the grinding disk 15. The rotation speed of the support table 14 was 17 rpm. The rotation speed of the grinding disk 15 was 680 rpm. The speed at which the grinding disk 15 approached the workpiece 11 was 20 μm/min.

Then, the workpiece 11 was ground to produce a SiC crystal 1. Abrasive grain trajectories 2 could be observed on a first surface 1A of the SiC crystal 1, and an intersection point 21 at which the abrasive grain trajectories 2 were most densely located was dislocated from a center C of the first surface 1A.

Next, a waviness curve of the first surface 1A of the SiC crystal 1 was measured. The waviness curve was measured in each of a <1-100> direction and an <11-20> direction. The waviness curve was measured using SURFCOM NEX 001 DX22 manufactured by Tokyo Seimitsu Co., Ltd. The waviness curve was measured in a portion excluding an outer peripheral region. A measurement length was 142 mm, which was obtained by excluding a range of 4 mm from each of the opposite ends of the diameter of 150 mm.

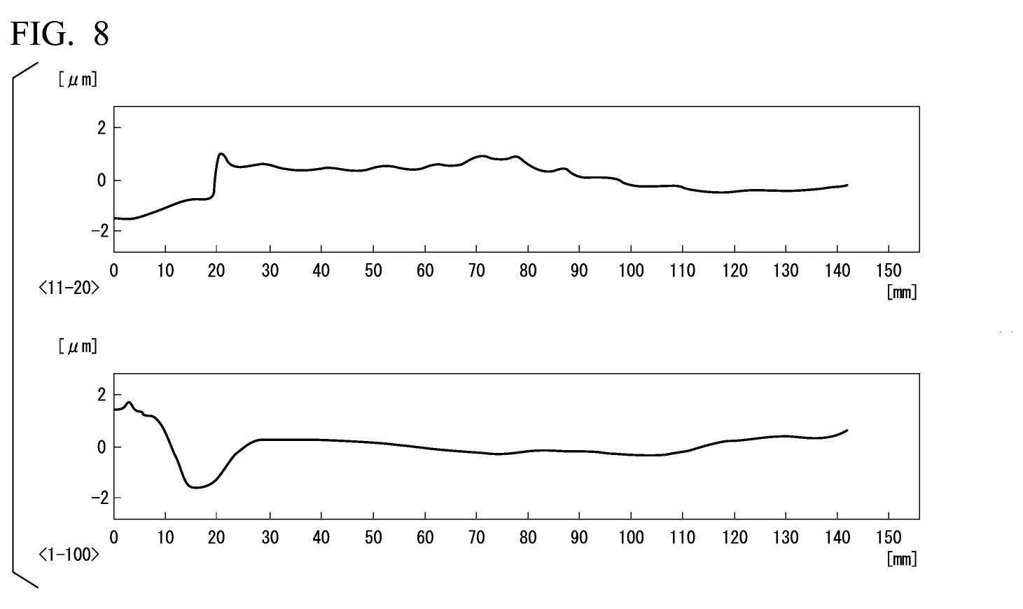

FIG. 8 shows a measurement result of the waviness curve of the first surface of the SiC crystal of Example 1. In FIG. 8, an upper diagram shows a result of measuring the waviness curve of the first surface in an <11-20> direction, and a lower diagram shows a result of measuring the waviness curve of the first surface in a <1-100> direction. A horizontal axis indicates a measurement position of the SiC crystal in a radial direction. With a position located 4 mm inward from one outer peripheral edge as a measurement starting point (0 mm), the measurement continues until a measurement ending point (142 mm), which is a position located 4 mm inward from the other outer peripheral edge, and a position at 71 mm is the center of the SiC crystal. A vertical axis indicates a height position of the first surface at each point of the SiC crystal in the radial direction.

As shown in FIG. 8, a lowest point of the waviness curve of Example 1 was dislocated from the center C in both the <11-20> direction and the <1-100> direction. A height difference between a highest point and a lowest point of the waviness curve measured in the <11-20> direction was 2.4665 μm. A height difference between a highest point and a lowest point of the waviness curve measured in the <1-100> direction was 3.2912 μm. A surface roughness Ra of the first surface measured in the <11-20> direction was 14.2 nm. A surface roughness Ra of the first surface measured in the <1-100> direction was 16.2 nm.

### Example 2

Example 2 is different from Example 1 in that a distance x between a center C14 of a support table 14 and a center C11 of a workpiece 11 is 100 mm. The other conditions were the same as in Example 1, and a SiC crystal of Example 2 was evaluated.

Abrasive grain trajectory 2 were also observed on a first surface 1A of a SiC crystal 1 of Example 2. A position at which the abrasive grain trajectories 2 were most densely located was dislocated from a center C of the first surface 1A.

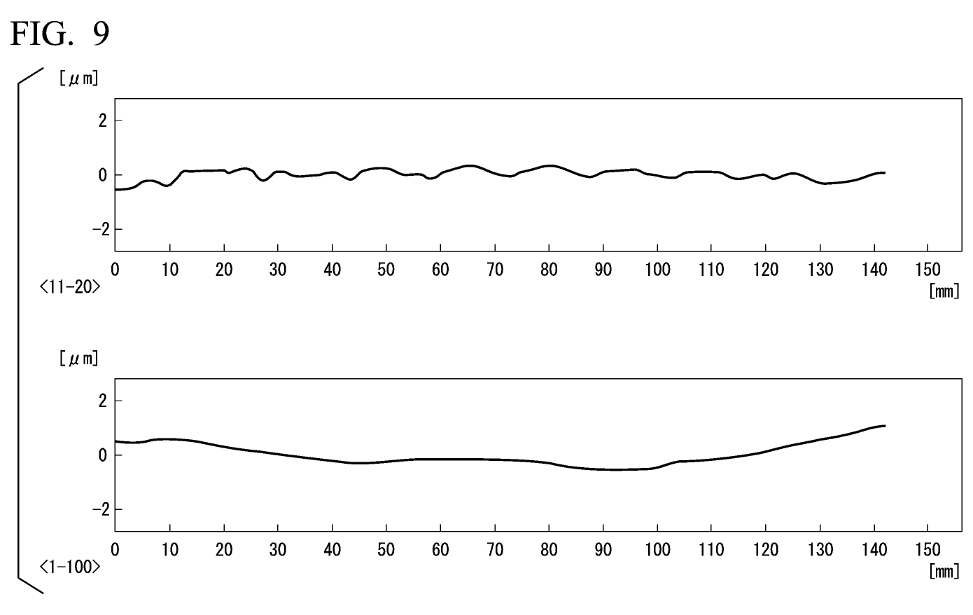

FIG. 9 shows a measurement result of a waviness curve of the first surface of the SiC crystal of Example 2. In FIG. 9, an upper diagram shows a result of measuring the waviness curve of the first surface in an <11-20> direction, and a lower diagram shows a result of measuring the waviness curve of the first surface in a <1-100> direction. A horizontal axis indicates a measurement position of the SiC crystal in a radial direction. With a position located 4 mm inward from one outer peripheral edge as a measurement starting point (0 mm), the measurement continues until a measurement ending point (142 mm), which is a position located 4 mm inward from the other outer peripheral edge, and a position at 71 mm is the center of the SiC crystal. A vertical axis indicates a height position of the first surface at each point of the SiC crystal in the radial direction.

As shown in FIG. 9, a lowest point of the waviness curve of Example 2 was dislocated from the center C in both the <11-20> direction and the <1-100> direction. A height difference between a highest point and a lowest point of the waviness curve measured in the <11-20> direction was 0.9233 μm. A height difference between a highest point and a lowest point of the waviness curve measured in the <1-100> direction was 1.6252 μm. A surface roughness Ra of the first surface measured in the <11-20> direction was 12.6 nm. A surface roughness Ra of the first surface measured in the <1-100> direction was 12.2 nm.

### Example 3

Example 3 is different from Example 1 in that a distance x between a center C14 of a support table 14 and a center C11 of a workpiece 11 is 200 mm. The other conditions were the same as in Example 1, and a SiC crystal of Example 3 was evaluated.

Abrasive grain trajectory 2 were also observed on a first surface 1A of a SiC crystal 1 of Example 3. A position at which the abrasive grain trajectories 2 were most densely located was dislocated from a center C of the first surface 1A.

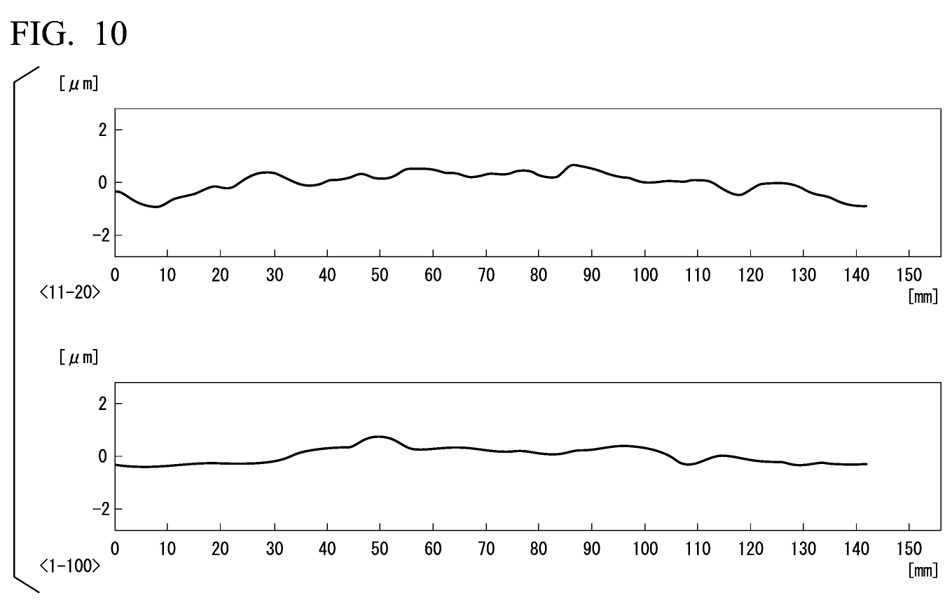

FIG. 10 shows a measurement result of a waviness curve of the first surface of the SiC crystal of Example 3. In FIG. 10, an upper diagram shows a result of measuring the waviness curve of the first surface in an <11-20> direction, and a lower diagram shows a result of measuring the waviness curve of the first surface in a <1-100> direction. A horizontal axis indicates a measurement position of the SiC crystal in a radial direction. With a position located 4 mm inward from one outer peripheral edge as a measurement starting point (0 mm), the measurement continues until a measurement ending point (142 mm), which is a position located 4 mm inward from the other outer peripheral edge, and a position at 71 mm is the center of the SiC crystal. A vertical axis indicates a height position of the first surface at each point of the SiC crystal in the radial direction.

As shown in FIG. 10, a lowest point of the waviness curve of Example 3 was dislocated from the center C in both the <11-20> direction and the <1-100> direction. A height difference between a highest point and a lowest point of the waviness curve measured in the <11-20> direction was 1.5813 μm. A height difference between a highest point and a lowest point of the waviness curve measured in the <1-100> direction was 1.1651 μm. A surface roughness Ra of the first surface measured in the <11-20> direction was 29.3 nm. A surface roughness Ra of the first surface measured in the <1-100> direction was 17.4 nm.

### Comparative Example 1

Comparative Example 1 is different from Example 1 in that a distance x between a center C14 of a support table 14 and a center C11 of a workpiece 11 is 0 mm. That is, in Comparative Example 1, the position of the center C14 of the support table 14 and the position of the center C11 of the workpiece 11 coincide with each other. The other conditions were the same as in Example 1, and a SiC crystal of Comparative Example 1 was evaluated.

Abrasive grain trajectory 2 were also observed on a first surface 1A of a SiC crystal 1 of Comparative Example 1. A position at which the abrasive grain trajectories 2 were most densely located was in a central portion C1 of the first surface 1A.

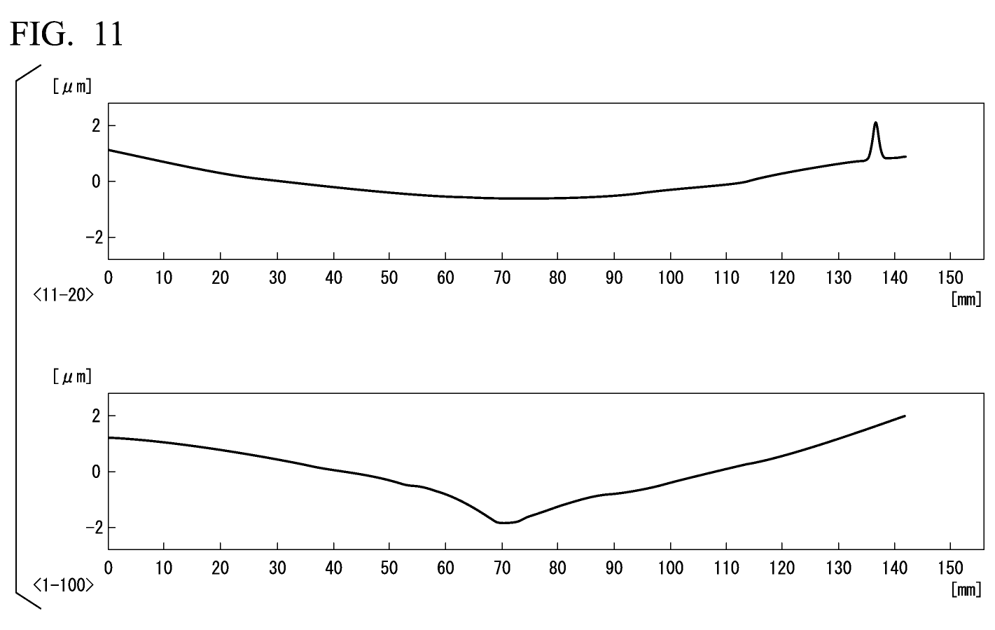

FIG. 11 shows a measurement result of a waviness curve of the first surface of the SiC crystal of Comparative Example 1. In FIG. 11, an upper diagram shows a result of measuring the waviness curve of the first surface in an <11-20> direction, and a lower diagram shows a result of measuring the waviness curve of the first surface in a <1-100> direction. A horizontal axis indicates a measurement position of the SiC crystal in a radial direction. With a position located 4 mm inward from one outer peripheral edge as a measurement starting point (0 mm), the measurement continues until a measurement ending point (142 mm), which is a position located 4 mm inward from the other outer peripheral edge, and a position at 71 mm is the center of the SiC crystal. A vertical axis indicates a height position of the first surface at each point of the SiC crystal in the radial direction.

As shown in FIG. 11, a lowest point of the waviness curve of Comparative Example 1 coincided with from the center C in both the <11-20> direction and the <1-100> direction. A height difference between a highest point and a lowest point of the waviness curve measured in the <11-20> direction was 2.7245 μm. A height difference between a highest point and a lowest point of the waviness curve measured in the <1-100> direction was 3.8233 μm. A surface roughness Ra of the first surface measured in the <11-20> direction was 17.3 nm. A surface roughness Ra of the first surface measured in the <1-100> direction was 12.0 nm.

In each of the SiC crystals of Examples 1 to 3, the lowest point of the first surface was dislocated from the center C of the first surface. In contrast, in the SiC crystal of Comparative Example 1, the lowest point of the first surface coincided with the center C of the first surface. In the joined body of the SiC crystals obtained using the SiC crystals of Examples 1 to 3, the joining interface was less likely to be misaligned when the joined body was cut with a multi-wire saw, compared to the joined body of the SiC crystals obtained using the SiC crystals of Comparative Example 1.

In addition, in each of the SiC crystals of Examples 1 to 3, the difference between the highest point and the lowest point of the first surface is smaller than that in the SiC crystal of Comparative Example 1. In the joined body of the SiC crystals obtained using the SiC crystals of Examples 1 to 3, variation in thickness of the SiC substrate was less likely to occur, compared to the joined body of the SiC crystals obtained using the SiC crystal of Comparative Example 1.

### Examples 4 to 6

Examples 4 to 6 are different from Examples 1 to 3 in that a thickness of a SiC crystal (SiC ingot) is 30 mm. Other conditions were the same as in Examples 1 to 3.

In each of the SiC crystals of Examples 4 to 6, a lowest point of a first surface was dislocated from a center C of the first surface. In addition, in each of the SiC crystals of Examples 4 to 6, a difference between a highest point and a lowest point of the first surface was 3.5 μm or less. In Examples 4 to 6, misalignment of the joining interface when cutting the joined body or variation in thickness of the SiC substrate after cutting, which was problematic, was not observed. It was observed that similar results could be obtained even in a case in which the thickness of the SiC crystal was great.

### Examples 7 to 9

Examples 7 to 9 are different from Examples 1 to 3 in that a thickness of a SiC crystal (SiC ingot) is 3 mm. Other conditions were the same as in Examples 1 to 3.

In each of the SiC crystals of Examples 7 to 9, a lowest point of a first surface was dislocated from a center C of the first surface. In addition, in each of the SiC crystals of Examples 7 to 9, a difference between a highest point and a lowest point of the first surface was 3.5 μm or less. In Examples 7 to 9, misalignment of the joining interface when cutting the joined body or variation in thickness of the SiC substrate after cutting, which was problematic, was not observed. It was observed that similar results could be obtained even in a case in which the thickness of the SiC crystal was small.

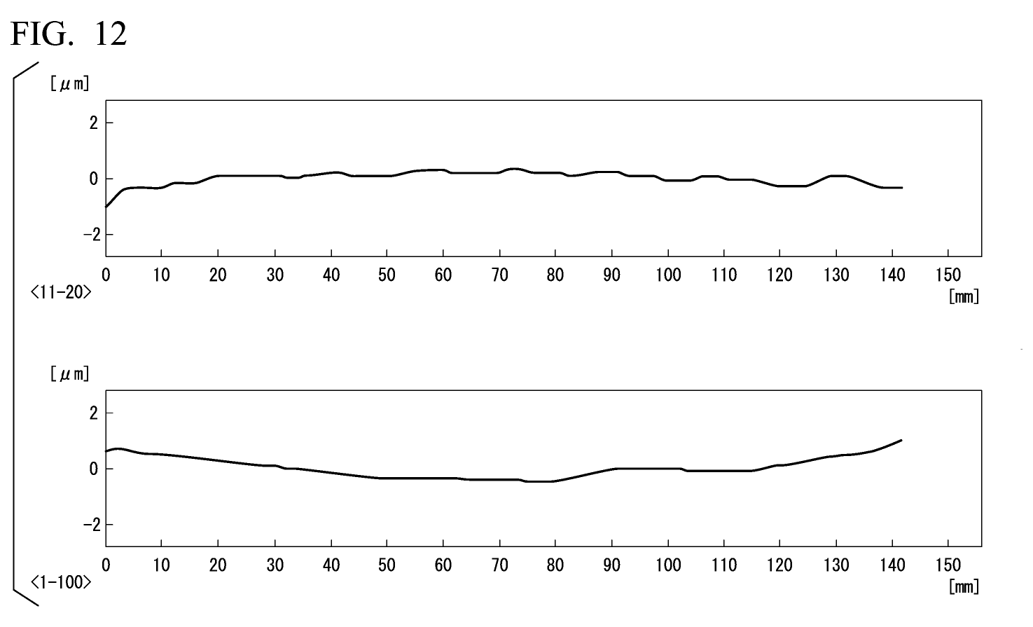

FIG. 12 shows a measurement result of a waviness curve of the first surface of the SiC crystal of Example 7 (the thickness of the SiC crystal (SiC ingot) is 3 mm, and a distance x is 50 mm). In FIG. 12, an upper diagram shows a result of measuring the waviness curve of the first surface in an <11-20> direction, and a lower diagram shows a result of measuring the waviness curve of the first surface in a <1-100> direction. A horizontal axis indicates a measurement position of the SiC crystal in a radial direction. With a position located 4 mm inward from one outer peripheral edge as a measurement starting point (0 mm), the measurement continues until a measurement ending point (142 mm), which is a position located 4 mm inward from the other outer peripheral edge, and a position at 71 mm is the center of the SiC crystal. A vertical axis indicates a height position of the first surface at each point of the SiC crystal in the radial direction.

As shown in FIG. 12, a lowest point of the waviness curve of Example 7 was dislocated from the center C in both the <11-20> direction and the <1-100> direction. A height difference between a highest point and a lowest point of the waviness curve measured in the <11-20> direction was 1.3538 μm. A height difference between a highest point and a lowest point of the waviness curve measured in the <1-100> direction was 1.5171 μm. A surface roughness Ra of the first surface measured in the <11-20> direction was 12.5 nm. A surface roughness Ra of the first surface measured in the <1-100> direction was 12.7 nm.

In addition, although the results obtained using a SiC crystal (SiC ingot) having a diameter of 150 mm (6 inches) were shown so far, a similar study was also carried out on a SiC crystal (SiC ingot) having a diameter of 200 mm (8 inches). In a case in which the diameter was 8 inches, the same tendency as the case in which the diameter was 6 inches was observed.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### EXPLANATION OF REFERENCES

1 SiC crystal

1A First surface

1B Second surface

1C Side surface

2 Abrasive grain trajectory

10 Grinding device

11 Workpiece

12 Plate

13 Work

14 Support table

15 Grinding disk

21 Intersection point

C, C11, C13, C14, C15 Center

C1 Central portion

L1 First measurement line

L2 Second measurement line

P1, P3 Lowest point

P2, P4 Highest point

What is claimed is:

1. A SiC crystal comprising a first surface which is one surface in a stacking direction,
wherein in a case where a waviness curve of the first surface is measured along a first measurement line that passes through a center of the first surface and extends in a <1-100> direction, a lowest point of the waviness curve on the first measurement line is dislocated from the center.

2. The SiC crystal according to claim 1, wherein in a case where a waviness curve of the first surface is measured along a second measurement line that passes through a center of the first surface and extends in an <11-20> direction, a lowest point of the waviness curve on the second measurement line is dislocated from the center.

3. The SiC crystal according to claim 1, wherein a surface roughness Ra of the first surface which is measured along the first measurement line is 20 nm or less.

4. The SiC crystal according to claim 1, wherein a surface roughness Ra of the first surface which is measured along a second measurement line that passes through a center of the first surface and extends in an <11-20> direction is 30 nm or less.

5. The SiC crystal according to claim 1,
wherein the first surface has abrasive grain trajectories, and
wherein an intersection point at which the abrasive grain trajectories overlap with each other most is dislocated from the center.

6. The SiC crystal according to claim 1, wherein a difference between a highest point and a lowest point of the waviness curve on the first measurement line is 3.5 μm or less.

7. The SiC crystal according to claim 2, wherein a difference between a highest point and a lowest point of the waviness curve on the second measurement line is 3.5 μm or less.

8. A SiC crystal comprising a first surface which is one surface in a stacking direction,
wherein in a case where a waviness curve of the first surface is measured along a first measurement line that passes through a center of the first surface and extends in a <1-100> direction, a difference between a highest point and a lowest point of the waviness curve on the first measurement line is 3.5 μm or less.

9. The SiC crystal according to claim 8, wherein in a case where a waviness curve of the first surface is measured along a second measurement line that passes through a center of the first surface and extends in an <11-20> direction, a difference between a highest point and a lowest point of the waviness curve on the second measurement line is 3.5 μm or less.

10. The SiC crystal according to claim 8, wherein a surface roughness Ra of the first surface which is measured along the first measurement line is 20 nm or less.

11. The SiC crystal according to claim 8, wherein a surface roughness Ra of the first surface which is measured along a second measurement line that passes through a center of the first surface and extends in an <11-20> direction is 30 nm or less.

12. The SiC crystal according to claim 8,
wherein the first surface has abrasive grain trajectories, and
wherein an intersection point at which the abrasive grain trajectories overlap with each other most is dislocated from the center.

13. The SiC crystal according to claim 8, wherein the lowest point of the waviness curve on the first measurement line is dislocated from the center.

14. The SiC crystal according to claim 9, wherein the lowest point of the waviness curve on the second measurement line is dislocated from the center.

15. The SiC crystal according to claim 1, wherein the SiC crystal has a diameter of 145 mm or greater.

16. A method for manufacturing a SiC crystal, comprising:
a step of placing a workpiece made of a SiC crystal on a support table; and
a step of grinding a first surface of the workpiece by bringing the workpiece placed on the support table rotating in a first direction into contact with a grinding disk rotating in a second direction opposite to the first direction,
wherein the grinding disk is disposed at a position facing the support table such that a center of the grinding disk does not coincide with a center of the support table, and
wherein a center of the workpiece is dislocated from the center of the support table.

17. The method for manufacturing a SiC crystal according to claim 16, wherein a distance between the center of the workpiece and the center of the support table is greater than or equal to a radius of the workpiece.

18. The method for manufacturing a SiC crystal according to claim 16, wherein a distance between the center of the workpiece and the center of the support table is equal to a radius of the workpiece.

19. The method for manufacturing a SiC crystal according to claim 16, wherein the workpiece has a diameter of 149 mm or greater.

20. The method for manufacturing a SiC crystal according to claim 16,
wherein in a case where a distance between the center of the workpiece and the center of the support table is defined as x and a rotation speed of the support table is defined as n, a peripheral speed of the support table at a placement position of the workpiece is 2πxn, and
wherein in a case where a speed at which the grinding disk approaches the workpiece is defined as f, 2πxn/f, which is a ratio of a cutting speed to the peripheral speed, satisfies 2πxn/f ≤ 1.03×10⁶.
